(19) United States
(12) Patent Application Publication
(10) Pub. No.: US 2020/0357835 A1
(43) Pub. Date: Nov. 12, 2020

(54) Variable-Width Source-Follower Transistor for Reduced Noise in CMOS Image Sensors

(71) Applicant: Gigajot Technology, Inc., Pasadena, CA (US)

(72) Inventor: Jiaju Ma, Pasadena, CA (US)

(21) Appl. No.: 16/855,876

(22) Filed: Apr. 22, 2020

Related U.S. Application Data
(60) Provisional application No. 62/844,213, filed on May 7, 2019.

(51) Int. Cl. H01L 27/146

(52) U.S. Cl. CPC H01L 27/14616; H01L 27/1463; H01L 27/14643; H01L 27/14689; H01L 27/14603

(57) ABSTRACT

An image sensor (e.g., an image sensor pixel) includes floating diffusion to receive charge, an output node to provide a voltage corresponding to the charge in the floating diffusion, a current supply, and a MOSFET in a source-follower configuration: the MOSFET includes a source coupled to the current supply and to the output node and a drain coupled to a voltage supply. The MOSFET also includes a gate coupled to the floating diffusion and a channel region disposed beneath the gate and having a length that extends between a source end where the channel region contacts the source and a drain end where the channel region contacts the drain. The channel region has a varying width; the drain-end width is wider than the source-end width.

### RELATED APPLICATIONS

This application claims priority to U.S. Provisional Patent Application No. 62/844,213, filed May 7, 2019, which is hereby incorporated by reference in its entirety.

### TECHNICAL FIELD

This disclosure relates to image sensors, and more specifically to CMOS image sensors with in-pixel source-follower transistors.

### BACKGROUND

Complementary metal-oxide-semiconductor (CMOS) image sensors have in-pixel source followers (i.e., in-pixel transistors in a source-follower configuration, which is also referred to as a common-drain configuration) to amplify and isolate the charge signal from the subsequent signal-processing circuitry. Because of the rapidly shrinking size of CMOS image-sensor pixels, the dimensions of the in-pixel source followers are being greatly reduced (e.g., to the hundreds of nanometers level). While this smaller size (i.e., area) helps to reduce the parasitic capacitance that source followers contribute to the respective floating diffusions in the pixels, it also leads to a higher probability of and magnitude for noise, such as random telegraph noise (RTN) and 1/f noise (i.e., noise for which the magnitude is inversely proportional to the frequency.

The in-pixel source followers in CMOS image sensors may be metal-oxide-semiconductor field-effect transistors (MOSFETs). RTN in MOSFETs is induced by the trapping and re-emission of channel carriers by energy states (i.e., traps), which are mostly located near the silicon-oxide interface. The trapping and re-emission of channel carriers causes a fluctuation of current between the source and drain terminals of respective MOSFETs. For a source-follower MOSFET biased by a current supply, this current fluctuation results in voltage noise (i.e., RTN) on the pixel's output node. The frequency and magnitude of the RTN vary depending on the location and relative energy of the energy states. As the size of the source follower decreases, the total number of majority carriers in the channel is reduced. Hence, the trapping and re-emission of individual carriers have a larger influence on the pixel output signal, and RTN with observable magnitude becomes more common, as the size decreases.

### SUMMARY

Accordingly, there is a need for source-follower transistors in CMOS image sensors with reduced noise, including reduced RTN.

In some embodiments, an image sensor (e.g., an image sensor pixel) includes floating diffusion to receive charge, an output node to provide a voltage corresponding to the charge in the floating diffusion, a current supply, and a MOSFET in a source-follower configuration: the MOSFET includes a source coupled to the current supply and the output node, wherein the current supply is coupled between the source and ground, and a drain coupled to a voltage supply. The MOSFET also includes a gate coupled to the floating diffusion and a channel region disposed beneath the gate and having a length that extends between a source end where the channel region contacts the source and a drain end where the channel region contacts the drain. The channel region has a varying width that includes a drain-end width and a source-end width. The drain-end width is wider than the source-end width.

In some embodiments, a method of fabricating an image sensor (e.g., of fabricating an image-sensor pixel) includes fabricating floating diffusion to receive charge, an output node to provide a voltage corresponding to the charge in the floating diffusion, and a current supply. The method also includes fabricating a MOSFET in a source-follower configuration. The MOSFET includes a source, drain, gate, and channel region. The source is coupled to the current supply and the output node, the current supply being coupled between the source and ground, and the drain is coupled to a voltage supply. The gate is coupled to the floating diffusion. The channel region is disposed beneath the gate and has a length that extends between a source end where the channel region contacts the source and a drain end where the channel region contacts the drain. The channel region has a varying width that includes a drain-end width and a source-end width. The drain-end width is wider than the source-end width.

In some embodiments, a method of operating an image sensor (e.g., of operating an image-sensor pixel) includes providing a MOSFET in a source-follower configuration: the MOSFET includes a source coupled to a current supply and an output node, wherein the current supply is coupled between the source and ground, and a drain coupled to a voltage supply. The MOSFET also includes a gate coupled to floating diffusion and a channel region disposed beneath the gate and having a length that extends between a source end where the channel region contacts the source and a drain end where the channel region contacts the drain. The channel region has a varying width that includes a drain-end width and a source-end width. The drain-end width is wider than the source-end width. The method also includes receiving charge in the floating diffusion and providing, from the source to the output node, a voltage corresponding to the charge in the floating diffusion.

Using a source-follower MOSFET with a channel region that is wider at the drain end than the source end reduces noise, including RTN, for the MOSFET and thus in the output signal for a pixel.

### BRIEF DESCRIPTION OF THE DRAWINGS

For a better understanding of the various described implementations, reference should be made to the Detailed Description below, in conjunction with the following drawings.

FIG. 1 is a circuit diagram of an example of a CMOS image-sensor pixel.

FIGS. 2A and 2B are respective front and side cross-sectional views of a typical MOSFET used in pixels of a CMOS image sensor.

FIG. 3 is a plan view of a transistor in which a portion of a channel region has a linear taper as defined by an insulator, such that the channel-region width is narrower at the source end than the drain end, in accordance with some embodiments.

FIG. 4 is a plan view of a transistor in which the entire channel region has a linear taper as defined by an insulator, such that the channel-region width is narrower at the source end than the drain end, in accordance with some embodiments.

FIGS. 5 and 6 are plan views of respective transistors in which an end portion of a channel region has a linear taper as defined by an insulator, such that the channel-region width is narrower at the source end than the drain end, in accordance with some embodiments.

FIG. 7 is a plan view of a transistor in which the source, channel region, and drain compose a substantially trapezoidal semiconductor region, such that the channel-region width is narrower at the source end than the drain end, in accordance with some embodiments.

FIG. 8 is a plan view of a transistor in which a channel region has a curved taper as defined by an insulator, such that the channel-region width is narrower at the source end than the drain end, in accordance with some embodiments.

FIG. 9 is a plan view of a transistor in which a portion of the channel region is tapered in a series of steps as defined by an insulator, such that the channel-region width is narrower at the source end than the drain end, in accordance with some embodiments.

FIG. 10 is a plan view of a transistor in which the variation in width of the channel region is provided by a single step such that the channel-region width is narrower at the source end than the drain end, in accordance with some embodiments.

FIG. 11 is a plan view of a transistor in which the variation in width of the channel region is provided by compensation doping such that the channel-region width is narrower at the source end than the drain end, in accordance with some embodiments.

FIG. 12 is a plan view of a transistor with a variable-width channel region in which the drain end has a lower threshold voltage than the source end, in accordance with some embodiments.

FIG. 13 is a flowchart showing a method of fabricating an image sensor in accordance with some embodiments.

FIG. 14 is a flowchart showing a method of operating an image sensor in accordance with some embodiments.

Like reference numerals refer to corresponding parts throughout the drawings and specification.

### DETAILED DESCRIPTION

Reference will now be made in detail to various embodiments, examples of which are illustrated in the accompanying drawings. In the following detailed description, numerous specific details are set forth in order to provide a thorough understanding of the various described embodiments. However, it will be apparent to one of ordinary skill in the art that the various described embodiments may be practiced without these specific details. In other instances, well-known methods, procedures, components, circuits, and networks have not been described in detail so as not to unnecessarily obscure aspects of the embodiments.

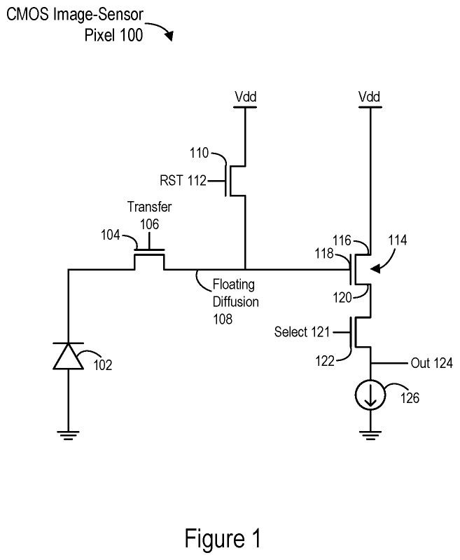

FIG. 1 is a circuit diagram of an example of a CMOS image-sensor pixel 100. The CMOS image-sensor pixel 100 includes a photosensitive element (e.g., photodiode) 102, transfer transistor 104, floating diffusion 108, reset transistor 110, source-follower transistor 114 (i.e., a transistor 114 in a source-follower configuration, as described below), one or more selection transistors (e.g., row-select and/or column-select transistors) 122, output node 124, and current supply (e.g., a constant current supply)(e.g., a load transistor) 126. The photosensitive element 102 generates electron-hole pairs, and thus accumulates charge, when illuminated. The photosensitive element 102 is selectively conductively coupled through the transfer transistor 104 to the floating diffusion 108. When a transfer signal 106 applied to the gate of the transfer transistor 104 is asserted, the transfer transistor 104 turns on and the accumulated charge is transferred through the transfer transistor 104 to the floating diffusion 108, which receives the charge. Before the transfer signal 106 is asserted, the floating diffusion 108 is reset to a reset voltage level by asserting a reset (RST) signal 112 applied to the gate of the reset transistor 110, thus turning on the reset transistor 110. The reset transistor 110 is coupled between the floating diffusion 108 and a voltage supply Vdd; the floating diffusion 108 is therefore selectively conductively coupled through the reset transistor 110 to Vdd. The transfer signal 106 is de-asserted, such that the transfer transistor 104 is turned off, while the RST signal 112 is asserted. The RST signal 112 is de-asserted, thus turning off the reset transistor 110, before the transfer signal 106 is asserted. The charge transferred to and received by the floating diffusion 108 causes the voltage level of the floating diffusion 108 to change from the reset voltage level to a voltage level corresponding to the amount of charge.

The source-follower transistor 114 includes a gate 118 that is conductively coupled (e.g., directly connected) to the floating diffusion 108, a drain 116 that is conductively coupled (e.g., directly connected) to Vdd, and a source 120 that is conductively coupled (e.g., selectively coupled through the selection transistor(s) 122) to the current supply 126 and to an output node (Out) 124. This configuration, with the drain 116 coupled to Vdd and the source 120 coupled to the current supply 126 and the output node 124, is known as a source-follower configuration and may also be referred to as a common-drain configuration. The selection transistor(s) 122 and current supply 126 are situated in series between the source-follower transistor 114 and ground, with the output node 124 situated between the source-follower transistor 114 and the current supply 126 (e.g., between the selection transistor(s) 122 and the current supply 126). The selection transistor(s) 122 are situated between the source-follower transistor 114 and the current supply 126.

Because the floating diffusion 108 is conductively coupled to the gate 118 of the source-follower transistor 114, the voltage level of the floating diffusion 108 is the gate voltage of the source-follower transistor 114. The gate voltage thus corresponds to the amount of charge received by the floating diffusion 108 and therefore to the intensity of light received by the photosensitive element 102. When a select signal 121 applied to the gate of the selection transistor(s) 122 is asserted, thus turning on the selection transistor(s) 122, the source 120 becomes conductively coupled to the output node 124 and pulls the output node 124 to a voltage corresponding to the charge received by the floating diffusion 108. In this manner, the source-follower transistor 114 generates an amplified signal indicative of the charge received by the floating diffusion 108 and thus the intensity of light received by the photosensitive element 102. This signal is provided through the output node 124.

A CMOS image-sensor pixel may include two source-follower transistors 114 arranged in parallel, with their gates 118 both conductively coupled (e.g., directly connected) to the floating diffusion 108, their drains 116 both conductively coupled (e.g., directly connected) to Vdd, and their sources 120 both conductively coupled (e.g., selectively coupled through the selection transistor(s) 122) to the current supply 126 and to the output node 124.

In the example of FIG. 1, the transfer transistor 104, reset transistor 110, source-follower transistor 114, and selection transistor(s) 122 are MOSFETs. For example, the transfer transistor 104, reset transistor 110, source-follower transistor 114, and/or selection transistor(s) 122 may be NMOS devices (i.e., MOSFETs with sources and drains doped n-type and channel regions doped p-type, wherein the channel regions may be biased to form inversion layers that act as n-type channels). Alternatively, one or more of these transistors, including for example the source-follower transistor 114, may be PMOS devices (i.e., MOSFETs with sources and drains doped p-type and channel regions doped n-type, wherein the channel regions may be biased to form inversion layers that act as p-type channels). A pixel 100 in which all of the transistors are NMOS devices is still considered a CMOS pixel, because it may be fabricated using respective steps in a CMOS processing technology and integrated with on-die CMOS logic circuitry.

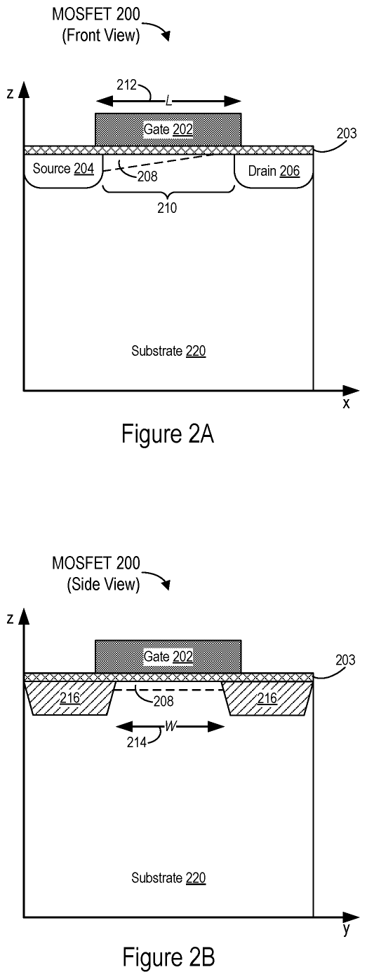

FIGS. 2A and 2B are respective front and side cross-sectional views of a MOSFET 200 (e.g., a silicon MOSFET) used in pixels of a CMOS image sensor (e.g., in the CMOS image-sensor pixel 100, FIG. 1). Respective instances of the MOSFET 200 may be examples of the transfer transistor 104, reset transistor 110, source-follower transistor 114, and/or selection transistor(s) 122. The MOSFET 200 includes a gate 202, gate insulator (e.g., gate oxide) 203, source 204, drain 206, and channel region 210 in which a channel 208 may form with suitable biasing of the gate 202. (While the “M” in MOSFET stands for “metal,” the gate 202 may be any conductive material, such as polysilicon, a silicide, or metal.) The gate 202 is situated above the channel region 210 and separated from the channel region 210 by the gate insulator 203. The channel region 210 has a length 212 (FIG. 2A) that extends along the x-axis between the source 204 and the drain 206, and has a width 214 (FIG. 2B) that extends along the y-axis between an insulator 216. In some embodiments, the insulator 216 is shallow-trench isolation (STI). Depending on biasing, the channel 208 may not extend across the entire length 212 of the channel region 210 (e.g., the channel 208 may pinch off). The channel 208 may be a surface channel or a buried channel. The MOSFET 200 is formed on a substrate 220; in some embodiments the MOSFET 200 is formed in a well (not shown) in the substrate 220. In some embodiments, the MOSFET 200 is an NMOS device, which may be formed in a p-well on the substrate 220. In other embodiments, the MOSFET 200 is a PMOS device, which may be formed in an n-well on the substrate 220.

The energy states (i.e., traps) that induce RTN in a MOSFET 200 used as the source-follower transistor 114 (FIG. 1) are caused by defects that are created in the MOSFET 200 during the fabrication process. The locations of these defects, and thus of the traps, are randomly distributed. The impact of a trap on the RTN in the signal provided to the output node 124 (FIG. 1) depends on the location of the trap (i.e., the location of the corresponding defect) in the channel region 210. Assuming a continuous current for the channel 208, the local current along the length of the channel region 210 should be constant. At a location xᵢ along the x-axis between the source 204 and the drain 206, the local current is given by:

I(xᵢ)=Dₑ(xᵢ)·W·d(xᵢ)·vₑ(xᵢ)=Nₑ(xᵢ)·vₑ(xᵢ), (1)

where Dₑ is the local electron density, Nₑ is the total number of electrons flowing through the cross-section (i.e., the cross-section at xᵢ in the y-z plane), W is the channel-region width 214, d is the depth of the channel 208, and vₑ is the electron velocity. Nₑ is also referred to as the local electron number. If the MOSFET 200 is biased in saturation mode, the local electron number in the channel is given by:

Nₑ(xᵢ)=W·Cₒₓ·[V_{g}−V_{c}(xᵢ)], (2)

where Cₒₓ is the unit capacitance of the gate oxide, V_{g} is the gate voltage, and V_{c} is the channel voltage. Because the channel voltage increases monotonically from the source 204 to the drain 206 (i.e., from the source end of the channel region 210 to the drain end of the channel region 210), the local electron number Nₑ decreases from the source 204 to the drain 206.

Under the assumption of a continuous current throughout the channel, a lower local electron number Nₑ near the drain end of the channel region 210 means a higher electron velocity vₑ near the drain end of the channel region 210: the electron velocity vₑ increases across the channel region 210 from the source 204 to the drain 206. When one electron is trapped or re-emitted by a trap, it introduces a relative current change given by:

$$\frac{dI}{I} = \frac{1}{{N}_{e} ( {x}_{i} )} . \qquad ( 3 )$$

Hence, because of a higher electron velocity vₑ and lower local electron number Nₑ, the RTN generated near the drain end of the channel region 210 has higher magnitude than the RTN generated near source end.

To reduce the RTN magnitude near the drain end of the channel region 210 and thereby improve the noise performance of the MOSFET 200 (e.g., of the source-follower transistor 114, FIG. 1), the width 214 of the channel region 210, and thus of the channel 208, is varied such that the width 214 is narrower at the source end of the channel region 210 than at drain end of the channel region 210 (i.e., the width 214 is wider at the drain end than at the source end). In some embodiments, the width 214 increases monotonically from the source end to the drain end. For example, the width 214 of the channel region 210 or a portion of the channel region 210 is tapered. In some embodiments, the varying width (e.g., the tapering) is defined by the surrounding insulator 216 (e.g., by STI) that bounds the channel region 210 on the y-axis (FIG. 2B). Alternatively, or in addition, the varying width (e.g., the tapering) is realized with a compensation implantation, such as a heavy p-type implantation for an n-channel source-follower transistor 114 (FIG. 1).

The local electron number Nₑ increases as the channel widens toward the drain end. The varying width 214 therefore at least partially compensates for the differences in electron velocity vₑ and local electron number Nₑ, along the length of the channel region 210, which result from the differences in the channel voltage V_{c} along the length of the channel region 210 (e.g., per equation 2). RTN near the drain end is thus reduced, per equation 3. Furthermore, a narrower width at the source end of the channel region 210 can reduce (e.g., minimize) the parasitic capacitance that the source-follower transistor 114 contributes to the floating diffusion 108 (FIG. 1), thereby improving the conversion gain of pixels (e.g., pixels 100, FIG. 1).

In some embodiments, the drain-end channel-region width 214 (i.e., the width 214 at the point on the x-axis where the channel region 210 meets the drain 206) is at least 20% wider than the source-end channel-region width 214 (i.e., the width 214 at the point on the x-axis where the channel region 210 meets the source 204), to effectively reduce the magnitude of RTN generated by the traps. In some embodiments, the drain-end channel-region width 214 is approximately 20% wider than the source-end channel-region width 214 (e.g., is 19-21% wider, or 18-22% wider). In some other embodiments, the drain-end channel-region width 214 is significantly more than 20% wider than the source-end channel-region width 214 (e.g., wider by an order of magnitude or more).

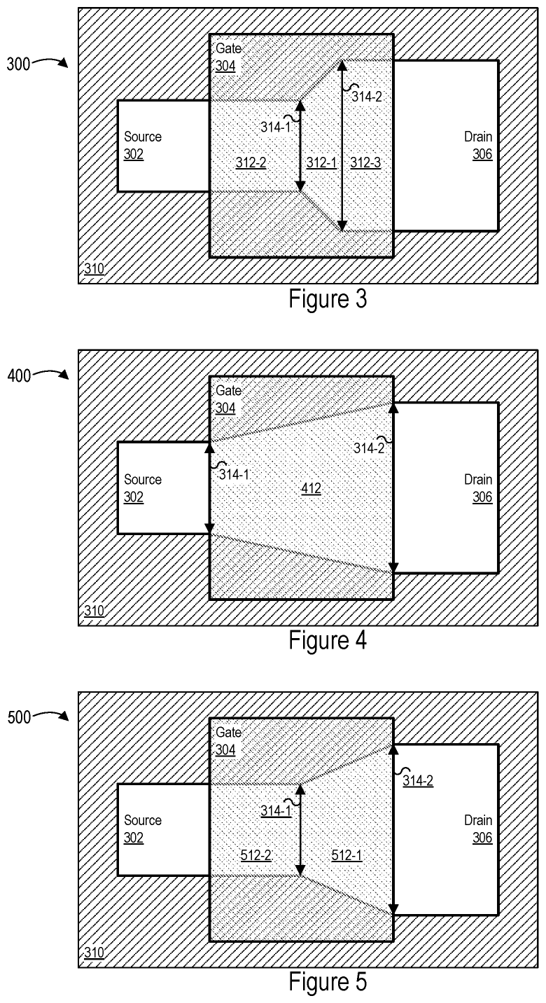

FIG. 3-10 are plan views of respective transistors with variable channel-region widths as defined by an insulator (e.g., STI), such that the channel-region width is narrower at the source end than the drain end, in accordance with some embodiments. The transistors of FIGS. 3-10 may be used as source-follower transistors in an image sensor. For example, the transistors of FIGS. 3-10 may be embodiments of the MOSFET 200 (FIG. 2) and/or the source-follower transistor 114 (FIG. 1).

FIG. 3 is a plan view of a transistor 300 in which a channel region 312 has a first region 312-1 with a linear taper (i.e., substantially linear, in straight lines to within manufacturing tolerances) as defined by an insulator 310, in accordance with some embodiments. The channel region 312 is situated beneath a gate 304 and extends lengthwise between a source 302 and a drain 306. (The gate 304 may partially overlap the insulator 310 as well.) The channel region 312 also includes a second region 312-2 with a constant source-end width 314-1 and a third region 312-3 with a constant drain-end width 314-2 that is wider than the source-end width 314-1. The first region 312-1 extends along a portion of the length of the channel region 312 between the second region 312-2 and the third region 312-3. The second region 312-2 extends along a portion of the length of the channel region 312 between the source 302 and the first region 312-1 (i.e., between the source end of the channel region 312 and the first region 312-1). The third region 312-3 extends along a portion of the length of the channel region 312 between the drain 306 and the first region 312-1 (i.e., between the drain end of the channel region 312 and the first region 312-1). The width of the first region 312-1 linearly tapers from the drain-end width 314-2 to the source-end width 314-1 along the −x direction. The transistor 300 thus is an example of a transistor (e.g., MOSFET 200, FIG. 2; source-follower transistor 114, FIG. 1) that narrows (e.g., tapers) along a portion of the length of the channel region.

FIG. 4 is a plan view of a transistor 400 in which the entire channel region 412 has a linear taper as defined by an insulator 310, in accordance with some embodiments. The channel region 412 is situated beneath the gate 304 and extends lengthwise between the source 302 and the drain 306. The width of the channel region 412 linearly tapers in the −x direction from the drain-end width 314-2 to the source-end width 314-1. The transistor 400 thus is an example of a transistor (e.g., MOSFET 200, FIG. 2; source-follower transistor 114, FIG. 1) that narrows (e.g., tapers) along the entire length of the channel region from the drain end to the source end.

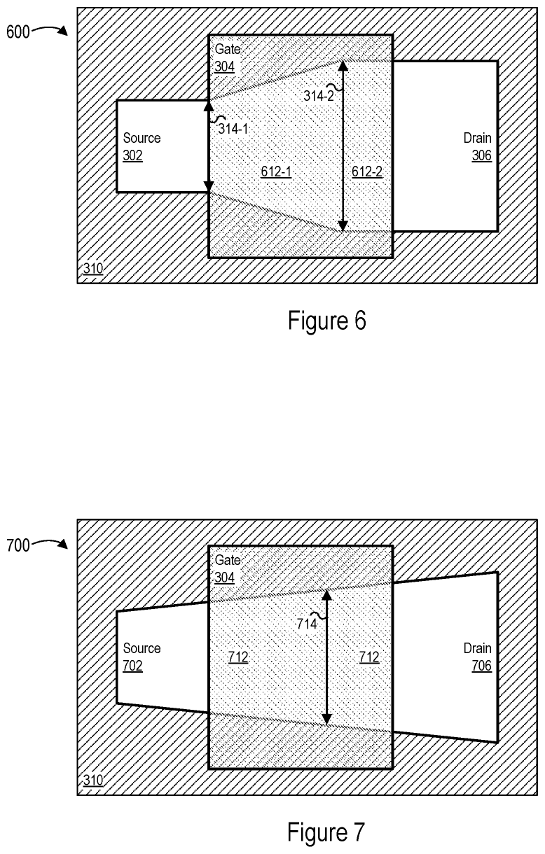

FIGS. 5 and 6 are plan views of respective transistors 500 and 600 in which an end portion of a channel region has a linear taper as defined by an insulator 310, in accordance with some embodiments. The transistors 500 and 600 have respective channel regions 512 and 612, which are situated under the gate 304. The channel region 512 (FIG. 5) includes a first region 512-1 and a second region 512-2. The first region 512-1 extends along a portion of the length of the channel region 512 between the drain 306 and the second region 512-2 (i.e., between the drain end of the channel region 512 and the second region 512-2). The second region 512-2 extends along a portion of the length of the channel region 512 between the source 302 and the first region 512-1 (i.e., between the source end of the channel region 512 and the first region 512-1). The second region 512-2 has a constant source-end width 314-1. The width of the first region 512-1 linearly tapers in the −x direction from the drain-end width 314-2 to the source-end width 314-1.

The channel region 612 (FIG. 6) includes a first region 612-1 and a second region 612-2. The first region 612-1 extends along a portion of the length of the channel region 612 between the source 302 and the second region 612-2 (i.e., between the source end of the channel region 612 and the second region 612-2). The second region 612-2 extends along a portion of the length of the channel region 612 between the drain 306 and the first region 612-1 (i.e., between the drain end of the channel region 612 and the first region 612-1). The second region 612-2 has a constant drain-end width 314-2. The width of the first region 612-1 linearly tapers in the −x direction from the drain-end width 314-2 to the source-end width 314-1.

The transistors 500 and 600 thus are additional examples of transistors (e.g., MOSFETs 200, FIG. 2; source-follower transistors 114, FIG. 1) that narrow (e.g., taper) along portions of the length of their channel regions.

FIG. 7 is a plan view of a transistor 700 in which the source 702, channel region 712, and drain 706 compose a substantially trapezoidal (e.g., trapezoidal to within manufacturing tolerances) semiconductor (e.g., silicon) region, in accordance with some embodiments. The channel region 712 is situated beneath the gate 304 and extends lengthwise between the source 702 and the drain 706. Far ends of the source 702 and drain 706 form the substantially (e.g., to within manufacturing tolerances) parallel sides of the trapezoid, as shown. The width 714 of the trapezoid tapers linearly from the far end (i.e., right side in FIG. 7) of the drain 706 to the far end (i.e., left side in FIG. 7) of the source 702, with the far end of the drain 706 being wider than the far end of the source 702. Accordingly, the width 714 of the channel region 712 tapers linearly from the drain end of the channel region 712 to the source end of the channel region 712. The transistor 700 is another example (in addition to the transistor 400, FIG. 4) of a transistor (e.g., MOSFET 200, FIG. 2; source-follower transistor 114, FIG. 1) that narrows (e.g., tapers) along the entire length of the channel region from the drain end to the source end.

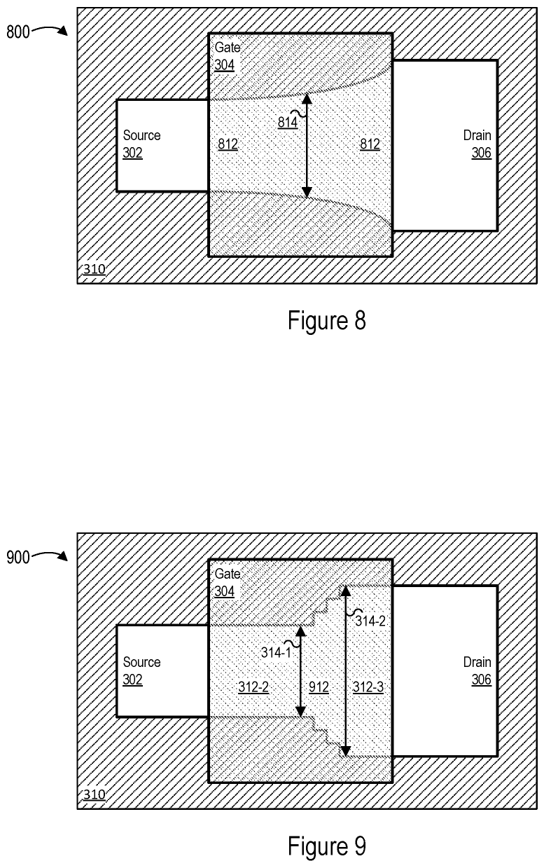

In some embodiments, instead of a linear taper as shown in FIGS. 3-7, the taper may be curved (e.g., on both sides). For example, parabolic or higher-order width gradients may be implemented. The curved taper may be substantially smooth (e.g., to within manufacturing tolerances). FIG. 8 is a plan view of a transistor 800 in which a channel region 812 has a curved taper as defined by an insulator 310, in accordance with some embodiments. The channel region 812 is situated beneath the gate 304 and extends lengthwise between the source 302 and the drain 306. The curved taper of the channel region 812 extends lengthwise from the drain end of the channel region 812 to the source end of the channel region 812, and thus extends along the entire length of the channel region 812. The transistor 800 therefore corresponds to the transistor 400 (FIG. 4), with the linear taper replaced by the curved taper. Alternatively, the curved taper may extend along only a portion of the length of the channel region 812. For example, the linear taper of the transistor 300 (FIG. 3), 500 (FIG. 5), 600 (FIG. 6), or 700 (FIG. 7) may be replaced with a curved taper.

In some embodiments, instead of a linear or curved taper, tapering is implemented using a series of steps. FIG. 9 is a plan view of a transistor 900 in which the channel region includes a first region 912 that is tapered in a series of steps as defined by an insulator 310, in accordance with some embodiments. The transistor 900 corresponds to the transistor 300, with the linear taper replaced by the stepped taper and the first region 912 corresponding to the region 312-1. Alternatively, the series of steps may extend along other portions of the length of the channel region or along the entire channel region. For example, the linear taper of the transistor 400 (FIG. 4), 500 (FIG. 5), 600 (FIG. 6), or 700 (FIG. 7) may be replaced with a series of steps.

In some embodiments, instead of using tapering, the variation of the channel-region width is implemented using a single step, as shown in FIG. 10 for a transistor 1000. The channel region 1012 of the transistor 1000 includes a source-end region 1012-1 with a constant source-end width 314-1 and a drain-end region 1012-2 with a constant drain-end width 314-2. The transition from the source-end region 1012-1 to the drain-end region 1012-2 occurs in a single step. The location of the step along the length of the channel region may vary for different embodiments.

In some embodiments, the variation in channel-region width is achieved entirely or partially using compensation doping (e.g., partially using compensation doping and partially using an insulator, such as STI). The channel region may be entirely or partially bounded along the y-axis (as defined in FIG. 2B) by compensation-doped semiconductor regions (e.g., p++ regions for the example of an NMOS device) that, because of the compensation doping, do not form an inversion layer and thus do not become part of the channel. Accordingly, the varying width of a channel region may be defined at least in part by regions of compensation-doped semiconductor that bound at least a portion of the channel region. Channel regions with any of the shapes discussed herein may be achieved using compensation doping instead of or in addition to an insulator 310.

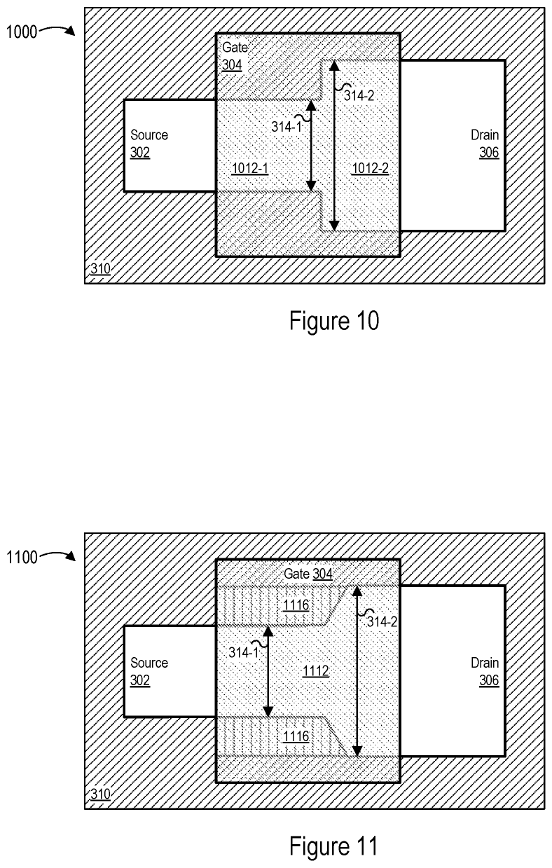

FIG. 11 is a plan view of a transistor 1100 in which the variation in width of the channel region 1112 is provided by compensation doping, in accordance with some embodiments. Regions 1116 of compensation-doped semiconductor bound a portion of the channel region 1112 width-wise and define the source-end width 314-1 and/or the taper. The drain-end width 314-2 is defined by the insulator 310, which bounds the drain-end of the channel region 1112 width-wise. In some other embodiments, regions of compensation-doped semiconductor may bound the entire region 1112 width-wise and define the source-end width 314-1, taper, and drain-end width 314-2.

In some embodiments, a threshold voltage (Vₜₕ) adjustment implantation can be applied to the drain end of the channel region to reduce the local Vₜₕ at the drain end. This drain-end Vₜₕ adjustment implant may be performed in addition to a Vₜₕ adjustment implant for the entire channel region. Reducing Vₜₕ at the drain end increases the local number of electrons Nₑ and reduces the electron velocity vₑ, thereby reducing RTN per equation 3. The drain-end Vₜₕ adjustment implant may be implemented together with varying (e.g., tapering) the channel-region width region as described herein, or may be performed without varying the channel-region width. For example, the drain-end Vₜₕ adjustment implant may be implemented for any of the transistors 300-1100 (FIGS. 3-11).

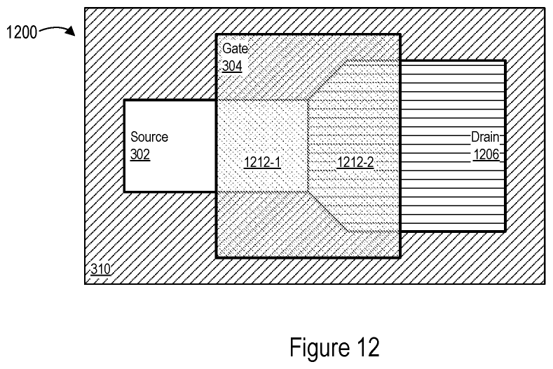

FIG. 12 is a plan view of a transistor with a variable-width channel region 1212 in which the drain end has a lower threshold voltage than the source end, in accordance with some embodiments. In the example of FIG. 12, the drain-end Vₜₕ adjustment implant is applied to a region 1212-2 that includes the drain end of the channel region and the tapered portion of the channel region and to the drain 306, but is not applied to the source end 1212-1 of the channel region or to the source 302. The region 1212-2 is an example of a first portion of the channel region, extending lengthwise into the channel region from the drain end, that has a lower threshold voltage than a remaining portion of the channel region that extends lengthwise into the channel region from the source end. In general, the boundary between the portion of the channel region that receives the drain-end Vₜₕ adjustment and the portion that does not may fall within the portion that has the drain-end width, the portion that has a tapered width, the portion that has the source-end width, or the location where the width steps from source-end width to the drain-end width.

The angle of taper of a linearly tapered channel region is an oblique angle, which may be 45° or an oblique angle that is not 45°. Design layout tools may only allow for 45° and 90° angles on reticles, and thus may not allow a line on a reticle to have an angle of taper other than 45°. A transistor with a linear taper at an angle other than 45°, or a transistor with a curved taper, may still be fabricated, however. The channel region border may be laid out, and thus specified on the reticle, in a series of steps at or near the minimum resolution allowed for the fabrication technology being used, and in accordance with other relevant design rules (e.g., rules for minimum sizing of design features), such that the stepped border averages out to the desired line or curve. As a result of the fabrication process, the border as printed on the die will be smoothed out as compared to the corresponding stepped structure on the reticle, thus substantially producing the desired line or curve.

In the examples of FIGS. 3-12, both the top and bottom sides of the channel region, or portions of the channel region, are tapered and/or stepped. In other examples, only the top or bottom side of the channel region, or a portion of the channel region, is tapered and/or stepped.

For embodiments in which a pixel includes two source-follower transistors 114 arranged in parallel, each of the source-follower transistors 114 (and their respective channel regions) may have any of the shapes disclosed herein. The two source-follower transistors 114 (and their respective channel regions) may have the same shape or different shapes.

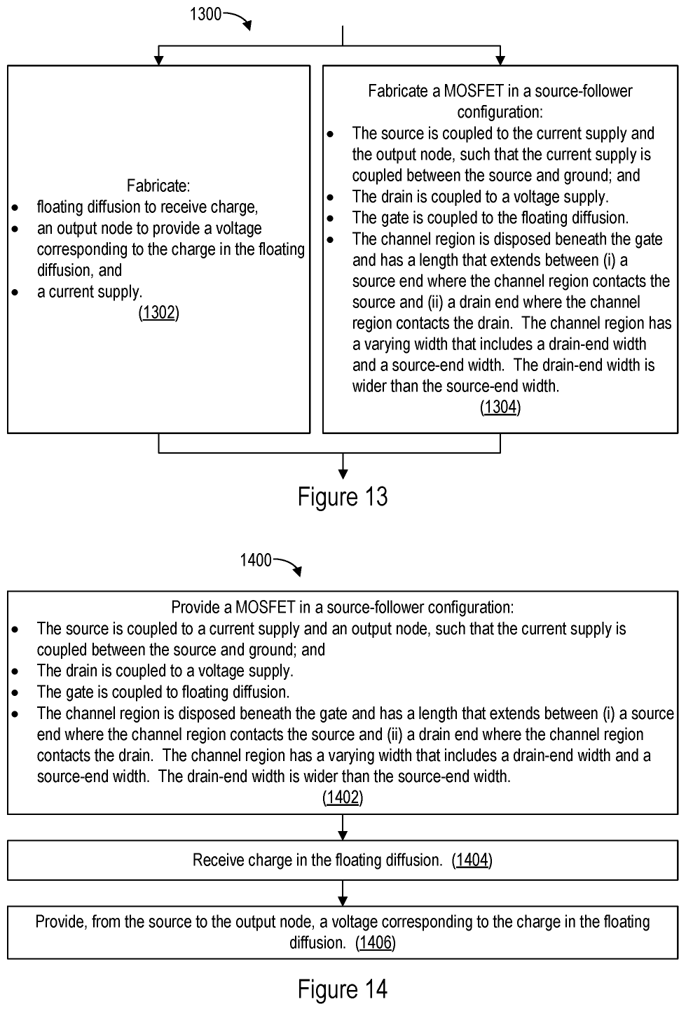

FIG. 13 is a flowchart showing a method 1300 of fabricating an image sensor (e.g., of fabricating a CMOS image-sensor pixel 100, FIG. 1, or other CMOS image pixel) in accordance with some embodiments. The method 1300 includes fabricating (1302) floating diffusion (e.g., floating diffusion 108, FIG. 1) to receive charge, an output node (e.g., output node 124, FIG. 1) to provide a voltage corresponding to the charge in the floating diffusion, and a current supply (e.g., current supply 126, FIG. 1). The method 1300 also includes fabricating (1304) a MOSFET (e.g., the source-follower transistor 114, FIG. 1, which may be an instance of the MOSFET 200, FIG. 2) in a source-follower configuration: the source is coupled to the current supply and the output node, such that the current supply is coupled between the source and ground, and the drain is coupled to a voltage supply. The channel region is disposed beneath the gate and has a length that extends between (i) a source end where the channel region contacts the source and (ii) a drain end where the channel region contacts the drain. The channel region has a varying width that includes a drain-end width and a source-end width. The drain-end width is wider than the source-end width. Examples of the fabricated source-follower MOSFET include, without limitation, any of transistors 300-1200 (FIGS. 3-12).

In some embodiments, the source-follower MOSFET of step 1304 is integrated on the same die as the floating diffusion, output node, and/or current supply of step 1302. For example, the source-follower MOSFET, floating diffusion, output node, and current supply are all integrated on a single die. In another example, the source-follower MOSFET, floating diffusion, and output node are integrated on a first die and the current supply is implemented in a second die that is coupled with the first die. The first and second die may be stacked (e.g., arranged in a stacked structure in a single package), with the first die on top and the second die situated beneath and bonded to the first die.

The method 1300 may be performed using standard CMOS fabrication techniques, with steps 1302 and 1304 being performed at least partially simultaneously. Additional fabrication steps may be performed before and after the steps 1302 and 1304. An image-sensor pixel fabricated in accordance with the method 1300 may provide a low-noise output signal via the output node.

FIG. 14 is a flowchart showing a method 1400 of operating an image sensor (e.g., of operating a CMOS image-sensor pixel 100, FIG. 1, or other CMOS image pixel) in accordance with some embodiments. In the method 1400, a MOSFET (e.g., the source-follower transistor 114, FIG. 1, which may be an instance of the MOSFET 200, FIG. 2) is provided (1402) in a source-follower configuration: the source is coupled to a current supply (e.g., current supply 126, FIG. 1) and an output node (e.g., output node 124, FIG. 1), such that the current supply is coupled between the source and ground, and the drain is coupled to a voltage supply. The gate is coupled to floating diffusion (e.g., floating diffusion 108, FIG. 1). The channel region is disposed beneath the gate and has a length that extends between (i) a source end where the channel region contacts the source and (ii) a drain end where the channel region contacts the drain. The channel region has a varying width that includes a drain-end width and a source-end width. The drain-end width is wider than the source-end width. Examples of the source-follower MOSFET include, without limitation, any of transistors 300-1200 (FIGS. 3-12). Charge (e.g., as transferred from the photosensitive element 102 through the transfer transistor 104, FIG. 1) is received (1404) in the floating diffusion. A voltage corresponding to the charge in the floating diffusion is provided (1406) from the source to the output node. The method 1400 thus generates and provides a low-noise output signal for an image-sensor pixel.

The foregoing description, for purpose of explanation, has been described with reference to specific embodiments. However, the illustrative discussions above are not intended to be exhaustive or to limit the scope of the claims to the precise forms disclosed. Many modifications and variations are possible in view of the above teachings. The embodiments were chosen in order to best explain the principles underlying the claims and their practical applications, to thereby enable others skilled in the art to best use the embodiments with various modifications as are suited to the particular uses contemplated.

1. An image sensor, comprising:
floating diffusion to receive charge;
an output node to provide a voltage corresponding to the charge in the floating diffusion;
a current supply; and
a metal-oxide-semiconductor field-effect transistor (MOSFET) in a source-follower configuration, comprising:
a source coupled to the current supply and the output node, wherein the current supply is coupled between the source and ground;
a drain coupled to a voltage supply;
a gate coupled to the floating diffusion; and
a channel region disposed beneath the gate and having a length that extends between a source end where the channel region contacts the source and a drain end where the channel region contacts the drain, the channel region having a varying width that includes a drain-end width and a source-end width, the drain-end width being wider than the source-end width.

2. The image sensor of claim 1, wherein the channel region is at least 20% wider at the drain end than at the source end.

3. The image sensor of claim 1, wherein the channel region is approximately 20% wider at the drain end than at the source end.

4. The image sensor of claim 1, wherein the channel region comprises a first region, extending along at least a first portion of the length of the channel region, in which the channel region narrows from the drain-end width to the source-end width.

5. The image sensor of claim 4, wherein the channel region further comprises a second region, extending along a second portion of the length of the channel region from the source end to the first portion, in which the channel region has the source-end width.

6. The image sensor of claim 4, wherein the channel region further comprises a third region, extending along a third portion of the length of the channel region from the first portion to the drain end, in which the channel region has the drain-end width.

7. The image sensor of claim 4, wherein the channel region further comprises:
a second region, extending along a second portion of the length of the channel region from the source end to the first portion, in which the channel region has the source-end width; and
a third region, extending along a third portion of the length of the channel region from the first portion to the drain end, in which the channel region has the drain-end width.

8. The image sensor of claim 4, wherein the first region extends along the entire length of the channel region from the source end to the drain end.

9. The image sensor of claim 4, wherein the channel region tapers from the drain-end width to the source-end width in the first region.

10. The image sensor of claim 9, wherein the taper in the first region is substantially linear.

11. The image sensor of claim 10, wherein the taper in the first region is curved.

12. The image sensor of claim 9, wherein the channel region tapers from the drain-end width to the source-end width in the first region in a series of steps.

13. The image sensor of claim 1, wherein the source, the channel region, and the drain compose a substantially trapezoidal semiconductor region in which far ends of the source and the drain are substantially parallel sides of the trapezoid, the far end of the drain being wider than the far end of the source.

14. The image sensor of claim 1, wherein the varying width of the channel region is defined by an insulator that bounds the channel region.

15. The image sensor of claim 14, wherein the insulator comprises shallow-trench isolation.

16. The image sensor of claim 1, wherein the varying width of the channel region is defined at least in part by regions of compensation-doped semiconductor that bound at least a portion of the channel region.

17. The image sensor of claim 1, wherein:
a first portion of the channel region, extending lengthwise into the channel region from the drain end, has a lower threshold voltage than a remaining portion of the channel region that extends lengthwise into the channel region from the source end.

18. The image sensor of claim 1, further comprising one or more selection transistors, situated between the source of the MOSFET and the current supply and output node, to selectively couple the source to the current supply and output node.

19. The image sensor of claim 1, further comprising a reset transistor, coupled between the floating diffusion and the voltage supply, to selectively reset the floating diffusion to a reset voltage.

20. A method of fabricating an image sensor, comprising:
fabricating floating diffusion to receive charge, an output node to provide a voltage corresponding to the charge in the floating diffusion, and a current supply; and
fabricating a metal-oxide-semiconductor field-effect transistor (MOSFET) in a source-follower configuration, the MOSFET comprising a source, drain, gate, and channel region, wherein:
the source is coupled to the current supply and the output node, the current supply being coupled between the source and ground;
the drain is coupled to a voltage supply;
the gate is coupled to the floating diffusion; and
the channel region is disposed beneath the gate and has a length that extends between a source end where the channel region contacts the source and a drain end where the channel region contacts the drain, the channel region having a varying width that includes a drain-end width and a source-end width, the drain-end width being wider than the source-end width.

21. A method of operating an image sensor, comprising:
providing a metal-oxide-semiconductor field-effect transistor (MOSFET) in a source-follower configuration, the MOSFET comprising:
a source coupled to a current supply and an output node, wherein the current supply is coupled between the source and ground;
a drain coupled to a voltage supply;
a gate coupled to floating diffusion; and
a channel region disposed beneath the gate and having a length that extends between a source end where the channel region contacts the source and a drain end where the channel region contacts the drain, the channel region having a varying width that includes a drain-end width and a source-end width, the drain-end width being wider than the source-end width;
receiving charge in the floating diffusion; and
providing, from the source to the output node, a voltage corresponding to the charge in the floating diffusion.
